(19) United States
(12) Patent Application Publication
(10) Pub. No.: US 2002/0187595 A1
(43) Pub. Date: Dec. 12, 2002

(54) Methods for silicon-on-insulator (SOI) manufacturing with improved control and site thickness variations and improved bonding interface quality

(75) Inventors: Hans J. Walitzki, Portland, OR (US); Kurt U. Dichmann, Banks, OR (US); Thomas J. Magee, Lake Oswego, OR (US); Claudian Nicolesco, Portland, OR (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Silicon Evolution, Inc., Vancouver, WA

(21) Appl. No.: 10/000,838

(22) Filed: Oct. 30, 2001

Related U.S. Application Data
(63) Continuation-in-part of application No. 09/632,642, filed on Aug. 4, 2000, now abandoned.
(60) Provisional application No. 60/147,432, filed on Aug. 4, 1999.

(51) Int. Cl. H01L 21/338

(52) U.S. Cl. 438/184

(57) ABSTRACT

A method for the production of silicon-on-insulator (SOI) wafers for controlling the device layer thickness variations and improvement of bonding quality at the interface of the wafers is disclosed. Using standard etched wafers, a unique sequence of process steps consisting of 2-step front side grinding, free-floating simultaneous double side polishing prepares wafers with low TTV and reduced edge roll off zones. The much smaller unbonded edge zone eliminates the requirements for edge grinding or etching in most cases. When the same s-step grinding/FFS-DSP sequence is applied after bonding and annealing of a Silicon-on-Insulator package, the resulting thickness variation in the device layer is usually smaller than what would be obtained from prior art processes.

### CROSS-REFERENCES TO RELATED APPLICATIONS

This application claims priority to and incorporates by reference U.S. patent application Ser. No. 09/632,642 filed Aug.4, 2000, which claims priority to U.S. Provisional Application No. 60/147,432 filed Aug. 4, 1999.

### BACKGROUND OF THE INVENTION

1. Field of the Invention

This invention relates generally to methods of production of silicon-on-insulator (SOI) wafers applicable to both thin and thick film processes. More particularly, the present invention pertains to an improved layer and interface quality especially close to the wafer's edge as well as a tighter control of device layer thickness and properties during wafer bonding and thinning processes.

2. Description of the Related Art

Silicon-on-insulator (SOI) structures are of great importance in microelectronic device technologies. SOI structures may consist of a thick inactive base layer, typically but not necessarily made of silicon, that provides mechanical stability, an electrically insulating intermediate layer, typically but not necessarily made of silicon dioxide (SiO₂), and a thin top layer of high-quality single-crystalline silicon which contains microelectronic devices which have been patterned into it, e.g. by photolithographic means. There are many thick and thin film SOI processes currently known in the industry. In an example of current thick film wafer bonding technologies, two polished wafers, for example a device wafer and a handle wafer, are joined together and bonded in a pair after an annealing step at high temperatures. Next, some thinning technologies, such as grinding and etching, are used to reduce the device wafer thickness to the appropriate geometry, thickness and surface properties of a final silicon layer, called a device layer. FIG. 1 shows a case where both a handle wafer 10 and a device wafer 20 are perfectly flat and clean and thus form a defect free bonded interface with an optional oxide layer 15. After reducing the device wafer to the desired thickness, the device layer 21 has little or no thickness variations across the entire wafer diameter. This is an idealized situation, which is typically not achieved in reality.

On regular wafers 30 such as the one shown in FIG. 2, surface irregularities such as dimples 31, mounds 32, edge-roll-off 33, waviness 34, edge-gutters 35, saw-marks, particles, and light-point-defects (LPD) (not shown), always exist to some extent. These irregularities are usually not critical for standard device manufacturing processes. However, in wafer bonding for SOI, the irregularities will cause defects and delamination of the bonded region and interface. Since almost all single side polished (SSP) wafers have such irregularities, the probability that these defects cancel each other is extremely low. Consequently, the yield for such prepared SOI wafers with satisfactory interface properties and overall uniformity is extremely low.

Some prior art techniques disclose a partial work-around by using double-side polished wafers (DSP) as substrates for bonding. Due to the double side polishing process, irregularities like 31, 32, 34 and 35 generally don't exist on DSP wafers. However, edge roll-off, reaching in as far as 5-10 mm into the wafer, can be a significant factor on DSP as well as on SSP wafers. In this “edge roll-off” zone, wafer bonding does not occur due to insufficient wafer flatness, illustrated in the region of reference designator 36 in FIG. 3. In the subsequent grinding and polishing steps to form a thin device layer, material from this zone would flake-off and particles generated thereby would scratch the surface. Therefore, prior to surface grinding, a top-edge grinding or etching step, which removes the material as shown near reference designator 41 in FIG. 4, is commonly applied to avoid this problem. This process, however, needs to be performed with high accuracy, adding considerable costs to the process.

Also shown in FIG. 4 is the geometrical relationship between handle wafer 10 and device wafer 20, and the effect that handle wafer TTV 43 has on the thickness variation, delta D 44, of the device layer. When the device silicon wafer is reduced in thickness to a few microns by grinding and/or polishing using a solid chuck or polishing plate as wafer support and a reference plane the thickness variation of the top silicon layer limits the application to film thickness of at least two times the TTV value of the handle wafer. This defines the requirements for wafers used in bonding related SOI wafer manufacturing processes as lowest possible TTV and smallest possible edge roll-off zone.

### BRIEF DESCRIPTION OF THE DRAWINGS

The present invention is described in conjunction with the appended figures:

FIG. 1 is a diagram which shows an idealized case of the prior art where both the handle and the device wafers are perfectly flat and clean and thus form a defect free bonded region;

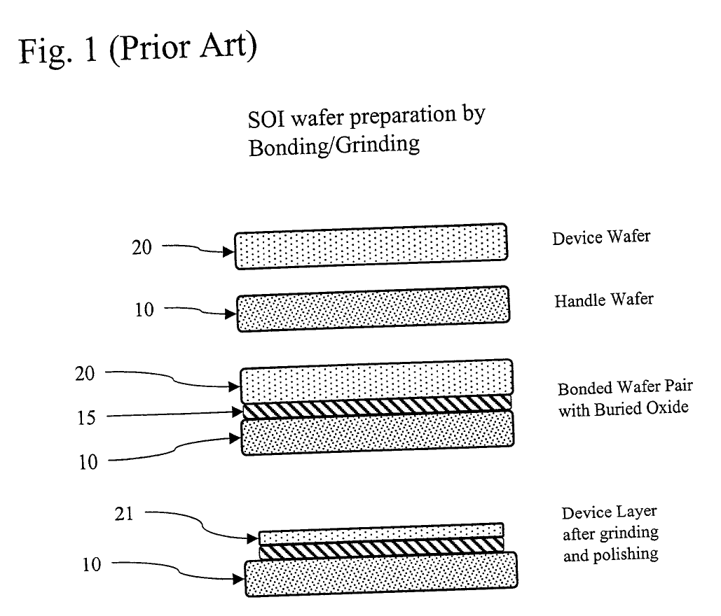

FIG. 2 is an illustration of an SSP wafer of the prior art showing various surface irregularities that commonly occur on the polished surface;

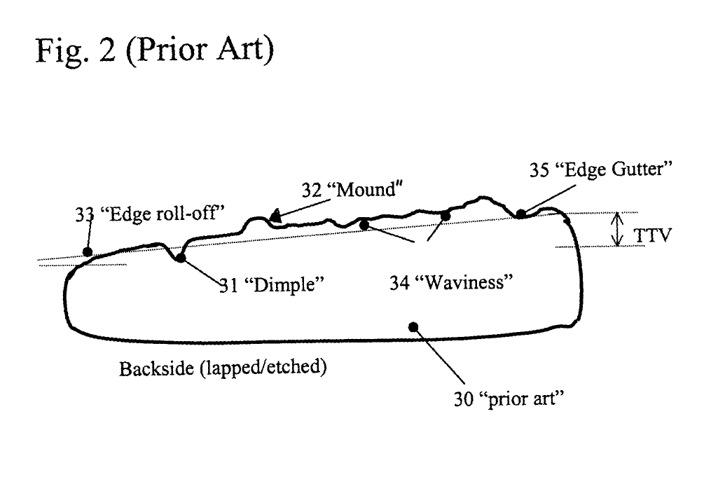

FIG. 3 illustrates the unbonded edge zone on a conventional double side polished wafer of the prior art compared to wafers prepared according to this disclosure.

FIG. 4 illustrates the geometrical relationship between the handle wafer and the device wafer, and the effect that the handle wafer has on the TTV of the device wafer during grinding when SSP wafer are used; also shown is the amount of unbonded material to be removed from the edge of the top wafer in the prior art.

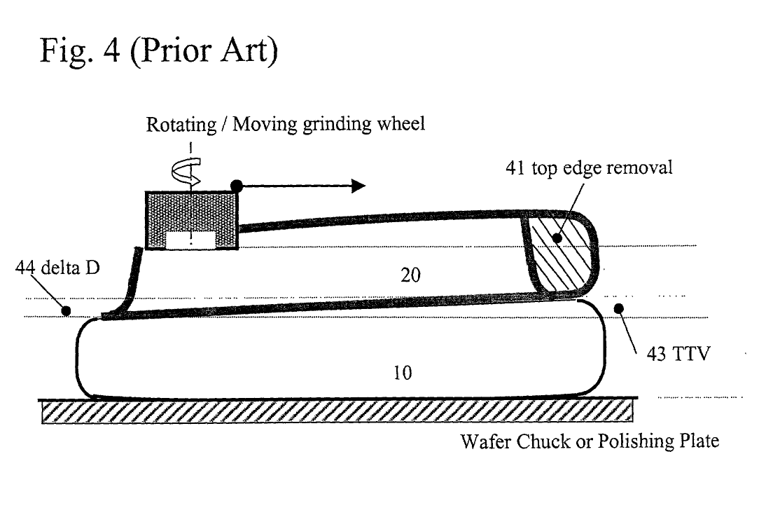

FIG. 5 illustrates an embodiment of the sequence of process steps used in our invention in contrast to the process steps used in prior art that are eliminated from our process.

FIG. 6 illustrates an embodiment of the improvement in flatness on the front side of wafers prepared with process sequence FIG. 5, wherethe backside has not been ground and has a edge-roll-off zone similar to the prior art.

FIG. 7 shows an embodiment of the SOI wafer package after Grinding (dashed lines) and after FFS-DSP to illustrate the improvement in Device layer tolerance by process sequence as disclosed in FIG. 5.

In the appended figures, similar components and/or features may have the same reference label.

### DESCRIPTION OF THE SPECIFIC EMBODIMENTS

The ensuing description provides preferred exemplary embodiment(s) only, and is not intended to limit the scope, applicability or configuration of the invention. Rather, the ensuing description of the preferred exemplary embodiment(s) will provide those skilled in the art with an enabling description for implementing a preferred exemplary embodiment of the invention. It being understood that various changes may be made in the function and arrangement of elements without departing from the spirit and scope of the invention as set forth in the appended claims.

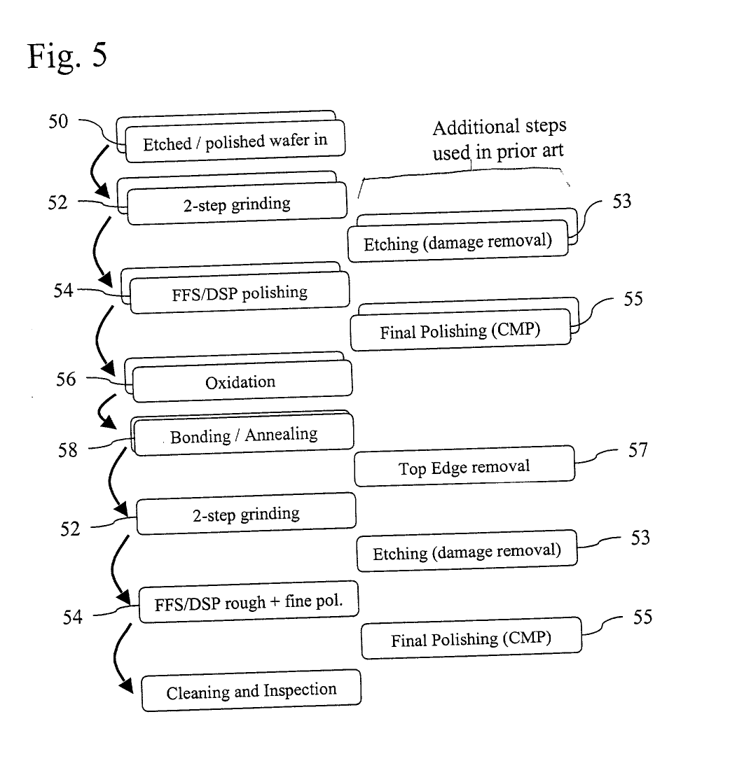

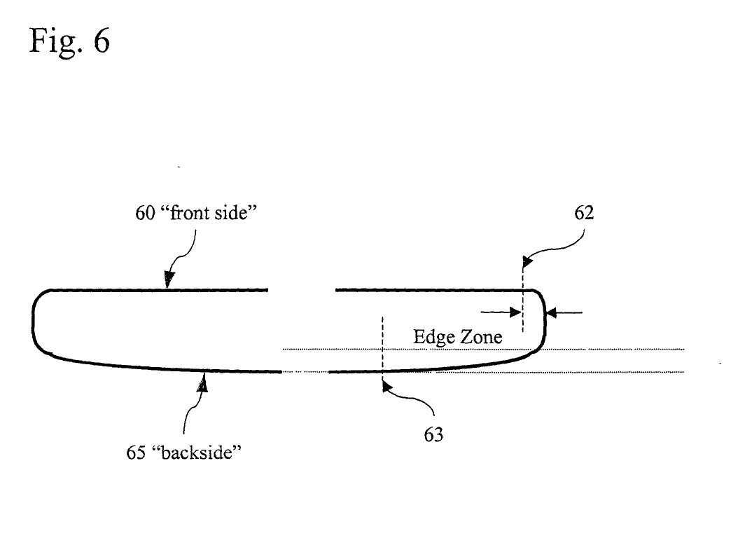

The present invention discloses a unique sequence of processing steps, one embodiment shown in FIG. 5, for the production of silicon-on-insulator (SOI) wafers. The invention provides wafer shapes as shown in FIG. 6 for illustration, resulting in improved layer interface quality and tighter control of the device layer thickness and properties than the other existing wafer bonding and wafer thinning processes, especially in a zone up to 10 mm from the wafer's circumference (edge). Also, since the process sequence relies upon fewer and less complicated process steps, the SOI wafers produced with our method can be made at higher overall yields and larger usable surface area at lower costs in one embodiment. The proposed process sequence method is applicable for the manufacturing of both, “thick” SOI films and of “thin” SOI films, used for advanced CMOS and other semiconductor device manufacturing.

In the present invention, the wafer's designated front (top) surface is first subjected to a precision 2-step grinding step 52 followed by an uniquely improved free-floating-simultaneous-double sided polishing (FFS-DSP) step 54. Unlike in the current state of art, due to the low degree of surface roughness and subsurface damage from the 2-step grinding process, no chemical etching 53 is required after grinding and prior to polishing. Elimination of etching, the use of selected carriers, and the integration of the final polishing step into FFS-DSP, generates wafers with a shape as shown in FIG. 6. The wafers are substantially free of dimples, mounds, waves, steps, and other surface non-homogeneities and defects and have a much smaller edge-roll-off zone 62 on the wafer front side 60 than conventionally polished wafers, shown as reference designator 63 in FIG. 6 on the wafer backside 65. TTV values on 20 0mm (8″) wafers of less than 0.3 μm can be obtained reproducibly in one embodiment. Our FFS-DSP process delivers a surface roughness and morphology after polishing that accomplishes defect free bonding up to a minimal (typically less than 1 mm) edge zone. No additional “final polishing” that would degrade the wafer flatness is required.

After bonding and annealing 58, the same two-stage grind process 52 is used again to remove material to specified thickness. The much smaller unbonded zone at the wafer circumference allows performance of this grinding step without prior top-edge removal 57 that is commonly required in the prior art. Another unique feature of this embodiment of our invention is the addition of additives for the reduction of cracking and subsurface damage in the 2-step grinding procedure 52 that will subsequently influence thickness variations and roughness after polishing. Due to this, other additional process steps that are usually required to remove the surface damage, like wet chemical etch removal 53 and/or plasma etch, are not required in the present invention, thus eliminating a deterioration of the excellent surface flatness obtained after grinding for this embodiment.

In order to further improve thickness variations in the device silicon layer, the same FFS-DSP process as was used in preparing the handle wafers is used after grinding. In this case, the newly generated front surface will follow exactly the original shape of the handle wafer's front surface, this further reducing the thickness variations of the top silicon layer compared to the prior art.

This process combination, will yield wafers with top layer thickness of 0.2 μm and higher and with a layer thickness tolerance of better than +/−0.1 μm for one embodiment without any additional process to control the thickness locally based on actual wafer measurements (like in PACE “trimming” which is very slow and expensive). The total process costs will be much lower than if ion implantation method is used for SOI wafers. The wafer quality and price will exceed the expectations of most CMOS applications for one embodiment.

For cost effective post-bonding thinning processes (grinding/polishing), the total thickness variation (TTV) within the wafers, as well as the wafer-to-wafer thickness range, needs to be less than 0.5 μm for 6″ and 8″ wafers in this embodiment. Wafers with these properties are defined as ultraflat, since regular polished wafers typically show TTV ranges of 3-5 μm and wider wafer-to-wafer thickness variations. In an embodiment, commercially available standard etched wafers 50 are prepared with our combination of 2-step grinding 52, followed by our improved FFP-DSP 54 using commercially available machines.

To achieve the desired “no-edge-roll-off” shape on the wafer front side in conjunction with improved wafer thickness variation, the future front side of the etched wafer is ground with our 2-step grinding process removing a minimum of 10 μm and typically about 30 μm of material prior to FFP-DSP for this embodiment. A grinding step of the backside is optional but usually not necessary. At this stage, the wafer has an asymmetric edge profile with a sharper corner at the front side as compares to the backside.

After grinding, the wafers are subjected to FFP-DSP with no prior cleaning or etching. The low subsurface damage after our 2-step grinding process before requires only 3 to 10 μm polishing removal off the front side; comparable to state of the art polishing processes on etched silicon wafers 53. Furthermore, the absence of chemical etching preserves the wafer flatness especially close to the edge. In a first phase of FFP-DSP, a larger amount of material is removed at a faster rate. This phase, called “rough polishing”, removes said 3-10 or more micrometers of material from front and backside simultaneously at a rate of 0.1-3 μm/min per side for this embodiment. The appropriate removal rate may be chosen according to specific requirements of the material to be polished, the desired process time and the total amount to be removed.

In one embodiment of the invention, the wafer back side is oxidized prior to FFP-DSP. In this case the removal rate on the back side can be made several orders of magnitude lower than on non-oxidized back sides without affecting the capability performance of the process with regards to flatness.

The wafer flatness and particularly the width of the edge roll-off zone is determined by the polishing pad, the carrier thickness and wafer rotation and translation across the polishing system. For minimal edge roll-off and optimal flatness the pads need to have a high shore hardness coefficient and the carriers shall not be thicker nor more than 30 μm thinner than the desired wafer thickness at the end of the process. To ensure optimal wafer spinning during polishing the rate of rotation increase (ramp-up) is another critical factor. High wafer rotation rates are achieved by generating a large velocity differences between wafer front surface/front polishing pad versus wafer back surface/back polishing pad under lower overall polishing pressures. Once the wafers spin freely it is found that equalizing the velocity difference under high overall polishing pressure keeps the wafers rotating and while greatly improving the flatness. Without this intermediate step it is found that the wafers don't rotate freely and thus become very tapered (wedge shaped) due to the hydro-dynamics between the polishing pads and wafer.

Using industry standard rough polishing slurries, the wafer surface roughness is typically between 2-3 nm. This is usually not smooth enough for wafer-to wafer bonding. Common practice to further reduce the surface roughness is to polish the wafers on a second or even third polishing machine 55 with slurries that use a finer grade of silica particles in a chemically less active solution, usually at a lower pH value than the first rough polishing step. For conventional DSP wafers this is usually done on single wafer, single side polishers, since there is no need for a smoother backside. While these “final polishers” achieve the required surface roughness for bonding, they nevertheless degrade the flatness of the wafers.

In our invention, this final polishing step (FP) is preferably performed on the same machine as used for the FFP-DSP rough polishing step by changing the composition of the polishing slurry towards the end of the polishing sequence. The rough-polishing slurry is replaced first with a mixture of rough and final polishing slurry to emulate an “intermediate” polishing step. Later, only final polishing slurry is fed to the polishing machine, completely replacing the rough slurry. We found the wafer carrier, being of approximately the same thickness as the targeted final wafer thickness, does an effective job of sweeping the polishing pad clean of the formerly used rough slurry. Consequently, we obtain final polish quality wafers with typically 0.2-0.4 nm surface roughness and practically no edge roll-off.

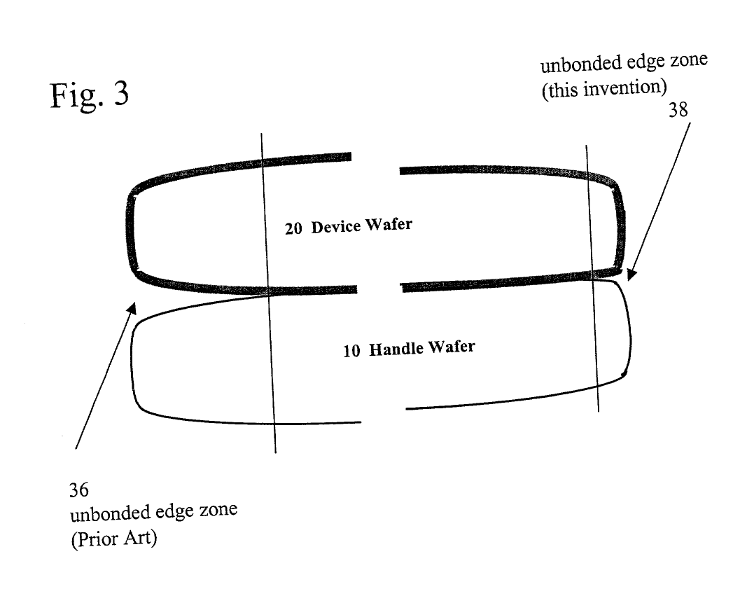

Some of the geometric advantages of our FFP-DSP process are illustrated in FIG. 6 for one embodiment. Using this process, values of TTV better than 0.5 μm with a uniform surface topography can be obtained. The edge roll-off zone 62 is found to be usually less than 1 mm, compared to 5-10 mm that is commonly observed on conventional wafers. If both, Handle and Device wafers are produced with this process sequence, the new resulting structure has a much smaller unbonded edge zone 38 as compared to the prior art unbonded edge zone 36 in FIG. 3.

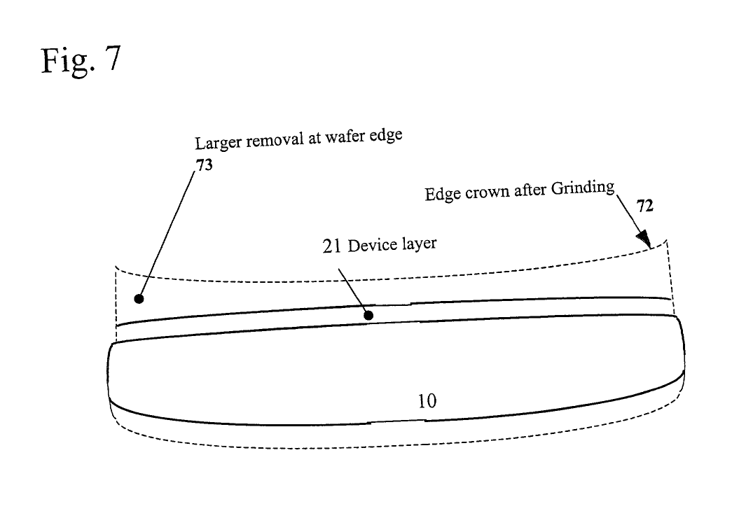

As shown in FIG. 7, further improvements will be realized when our FFS-DSP is applied again after bonding and grinding. The dashed lines 72 represent the wafer surface after the 2-step grinding process. The slight convex shape of the wafer backside will translate into an equivalent center-to edge thickness variation in the device layer. This usually leads to an elevated circumferal edge zone, the edge crown 72 in FIG. 7. In FFS-DSP this zone will be subjected to higher initial pressure and shear force against the polishing pad and therefore be polished at a faster rate compared to the wafer center until the process determined, slight bi-convex shape of the wafer is re-established. Thus the shape of the original front surface is regenerated on the new device layer and the thickness variation is smaller that what would be calculated from the Handle wafer TTV in the prior art. In one embodiment, we have generated SOI wafers with an average thickness of the top layer of 0.50 μm and a variation of less 0.1 μm (all point measurement) from Handle wafers with 0.5 μm TTV.

In the creation of a thin film SOI wafer, the disclosed process sequence avoids issues such as the use of an expensive ion implantation process, the so-called implantation damage and the implantation related metal contamination. The process delivers wafers free of dimples, mounds, waves, steps, and other surface non-homogeneities and defects. The much smaller edge roll-off than conventional techniques eliminates the otherwise necessary edge grinding or edge etching steps. In addition, TTV values on 200 mm (8″) wafers of less than 0.5 μm can be reproduced in a very cost effective manufacturing process.

The following description illustrates an example using the disclosed process. Commercially available etched wafers are first ground and the polished with our FFP-DSP processes. Particles and residues are then removed from surfaces using a sponge roller scrubber with a surfactant/water mixture. After rinsing, the wafers are then dried in a laminar flow area. Next, a SiO₂ layer of 1 μm thickness was grown by wet oxidation at 1050 degrees C. onto the surfaces of the device wafers.

The device wafers were then bonded to Handle wafers using available bonding equipment. Upon completion of the bonding process, the handle wafer/device wafer packages are annealed at 1200 degrees C. for approximately 2 hours in nitrogen gas. The wafers are then removed and placed on the stage of a flat disk-grinding machine with a variable flow rate glycol feed jet installed. The top surface of the device wafer is ground using a two-stage process with a variable flow glycol on the wheels.

The conditions for the two-stage grind process are listed below in Table 1. The first stage produces a roughness of 20 nanometers, and the second stage of the process results in a roughness of 5 to 10 nanometers. The two-stage process with variable flow rate control of glycol onto the surface produces a reduction in micro cracking, chipping, and subsurface damage at depths onto the surface. This will then produce a surface requiring reduced removal in subsequent polishing steps. In all cases material is removed to a depth of approximately 20 μm.

TABLE 1
Parameters for a Two Step Grind Process

| | First Stage | Second Stage |
|---|---|---|
| Manufacturer grind disk | Norton | Norton |
| Abrasive grain size | 2-3 μm (2,000 | 3-5 μm (3,000 mesh |
| | mesh vitrified) | resin bonded particles) |
| Pressure | 35-40 psi | 35-40 psi |
| Surfactant | Glycol (variable | Glycol (variable Feed) |
| | Feed) | |
| Wafer notation rate | 590 rpm | 590 rpm |
| Grind wheel rotation | 4100 rpm | 4100 rpm |
| Rate | | |
| Removal rate | 9 μm/sec | 1 μm/sec |
| Roughness | 18-20 nm | 3-10 nm |

After cleaning, the bonded device wafer/handle wafer packages are mounted on the wheels of a FFS-DSP machine for polishing of both surfaces. In this process, a variable flow rate valve can be installed to allow programmed flow of slurries onto the surfaces, permitting programmed thickness removal rates to be done. In this case, the removal rate is varied during process from 1.5 μm/min. to 0.8 μm/ min. This procedure permits a reduction in roll off and annihilation of roughness after grinding. In addition, it reduces the severity of “chemical drive-in” effects of etching along subsurface damage lines indeed by the grinding process. Since there is a charge interaction between the charged defect sites and the surfactant, altered flow at the later stages will substantially reduce the removal and extended etching by a screening effect.

When the desired stock removal is achieved (controlled by in-situ thickness measurement or simply time based controlled when the removal rate is known from prior polishing runs) the final step is performed by first adding a industry standard final polishing slurry to the rough slurry. After a few minutes at increased slurry flow from the combination of both slurries, the rough slurry flow is switched off. Final polishing continues for a few more minutes after which this slurry is turned-off also while a high flow of DI water is fed through the slurry supply lines to stop the chemical reaction and rinse the wafers in-situ. A final touch-polishing step involving a chemical-mechanical polishing (CMP) step using a Strasbaugh model 6DSSP machine, removing a few nm from the front surface is optional but usually not necessary for wafer bonding. Upon completion of the final polishing step, either on the FFP-DSP machine or an additional CMP machine, the wafers are rinsed and quickly dipped in HF, and then subjected to an RCA clean. Following a quick rinse, the wafers are then subjected to a particle-clean using an automated system such as a sponge scrub roller and a surfactant. The wafers are then removed, rinsed and subjected to a laminar flow dry.

Table 2 below shows the data obtained on thickness variations at points across wafers subjected to the processes outlined in this invention. In each case the range of variation is less than one micron. Table 3 summarizes the device layer data for the wafers of Table 2.

TABLE 2
Thickness of Device Layer
(After 2-step Grind and FFS-DSP)

| Measurement | Thickness (μm) | Thickness (μm) |
|---|---|---|
| Site | Wafer A | Wafer B |
| 1 | 3.42 | 3.16 |
| 2 | 3.28 | 2.92 |
| 3 | 3.27 | 2.83 |
| 4 | 3.37 | 2.87 |
| 5 | 3.21 | 3.04 |
| 6 | 3.13 | 2.41 |
| 7 | 3.14 | 2.56 |
| 8 | 2.96 | 2.29 |
| 9 | 2.85 | 2.23 |

TABLE 3
Device Layer Data for the Wafers of Table 2

| Parameter | Wafer A | Wafer B |
|---|---|---|
| Mean thickness (μm) | 3.18 | 2.70 |
| Standard Deviation (μm) | 0.187 | 0.33 |
| % Standard Deviation (% | 5.867 | 12.571 |
| Minimum thickness (μm) | 2.85 | 2.23 |
| Maximum thickness (μm) | 3.85 | 3.16 |
| Thickness range (μm) | 0.58 | 0.93 |

Inspection of the handle/device wafer packages in the IR microscope after bonding was done on a number of wafers at a temperature of 40 degrees Celsius. In all cases, inspection was done prior to grinding and annealing of the bonded wafer pair. The bonding interface was shown to be free of voids and irregularities with no permanent surface defects driven from the interface. In contrast, standard SSP wafer packages did show pronounced bond irregularities and voids especially in a 5-10 mm edge zone, as anticipated.

While the principles of the invention have been described above in connection with specific apparatuses and methods, it is to be clearly understood that this description is made only by way of example and not as limitation on the scope of the invention.

What is claimed is:

1. A method of producing silicon on insulator (SOI) wafers, comprising:
providing a low-damage/low roughness 2-step grinding process to obtain flat wafer surfaces at least on one side (front side) and a sharper corner at least on the designated front side of the wafers,
subjecting said wafers a FFS-DSP process to remove the sub-surface damage and adjust the surface roughness to values of less than about 0.5 nm by adding a commercially available final polishing slurry and later stopping the feed with rough polishing slurry while the thickness of the carriers holding the wafers between the polishing pads and moving them across the pads' surfaces is not larger and not more than about 30 μm thinner than the final wafer thickness at the end of the FFP-DSP sequence
providing a plurality of DSP wafers, a first wafer comprising a device wafer and a second wafer comprising a handle wafer;
growing a thermal oxide on at least one of said wafers;
bonding said first and second wafer on commercially available equipment using at least one vacuum chuck to impose a slight convex curvature on at least one of the wafers to an undisturbed center-to-edge bonding wave;
annealing said wafer package;
performing a two stage grinding procedure on the wafer package;
performing again a FFS-DSP procedure using a variable rate slurry feed to alter removal rates during polishing and performing a final polishing procedure on said FFS-DSP machine by adding a commercially available final polishing slurry and later stopping the feed with rough polishing slurry, while the thickness of the carriers holding the wafers between the polishing pads and moving them across the pads' surfaces is not larger and not more than about 30 μm thinner than the final wafer thickness at the end of the FFS-DSP sequence.

2. The method of claim 1, wherein said thermal oxide layer is no greater than 3 μm.

3. The method of claim 1, wherein no thermal oxide is grown (direct wafer-to-wafer bonding.

4. The method of claim 1, wherein said two stage grinding procedure comprises a course grind and a fine grind in the presence of a variable flow coolant stream which includes glycol or other surfactants to minimize the surface roughness and subsurface damage.

7. The method of claim 1, wherein the ground wafer is subjected to FFS-DSP with no intermediate etching or cleaning.

5. The method of claim 1, wherein said first and second wafers comprise mono-crystalline silicon.

6. The method of claim 1, wherein said first and second wafers comprise multi-crystalline silicon.

7. The method of claim 1, wherein said first and second wafers comprise poly-crystalline silicon.

8. The method of claim 1, wherein said first and second wafers are not silicon.

9. The method of claim 1, wherein said first wafer comprise silicon and said second wafer is not silicon.

10. The method of claim 1, wherein said second wafer comprise silicon and said first wafer is not silicon.

11. The method of claim 1, wherein said first and second wafers are further ground on the back side after bonding and annealing to adjust thickness.

12. A method for silicon-on-insulator manufacturing as described in the specification and drawings.
